(19) United States
(12) Patent Application Publication
(10) Pub. No.: US 2025/0306460 A1
(43) Pub. Date: Oct. 2, 2025

(54) ORGANOTIN COMPOUNDS AS PHOTORESISTS, AND/OR PRECURSORS

(71) Applicant: Feng Lu, Irvine, CA (US)

(72) Inventor: Feng Lu, Irvine, CA (US)

(21) Appl. No.: 19/093,733

(22) Filed: Mar. 28, 2025

Related U.S. Application Data
(60) Provisional application No. 63/572,312, filed on Mar. 31, 2024.

(51) Int. Cl. G03F 7/004; C07F 7/22; G03F 7/00

(52) U.S. Cl. CPC G03F 7/0042; C07F 7/226; G03F 7/0046; G03F 7/70033

(57) ABSTRACT

Organotin compounds bearing cyclopentadienyl, sulfur, selenium, or tellurium as photoresists, and/or precursors for photolithography patterning, or thermoelectric materials, are described, particularly for extreme ultraviolet radiation (EUV), wherein cyclopentadienyl comprises cyclopentadienyl C₅H₅ group, or substituted cyclopentadienyl C₅H₃R, CH₂R₂, C₅HR₃, C₅R₄, or C₅R₅ group with hapticity of η¹, η², η³, η⁴, or η⁵ of isomers.

### CROSS REFERENCE TO RELATED APPLICATIONS

This application claims priority to U.S. provisional patent application No. 63/572,312 filed on Mar. 31, 2024 to Lu, entitled “Organotin compounds as photoresists, and/or precursors”, of which is entirely incorporated herein by reference.

### FIELD OF INVENTION

The present invention relates to organotin compounds bearing cyclopentadienyl, sulfur, selenium, or tellurium as photoresists, and/or precursors for photolithography patterning, or thermoelectric materials, particularly for extreme ultraviolet radiation (EUV), wherein cyclopentadienyl comprises cyclopentadienyl C₅H₅ group, or substituted cyclopentadienyl C₅HAR, C₅H₃R₂, C₅H₂R₃, C₅HR₄, or C₅R₅ group with hapticity of η¹, η², η³, η⁴, or η⁵ of isomers.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light absorption because metals have high absorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Among those promising advanced materials, particularly organometallic tin (organotin) compounds can provide photoresist patterning with significant advantages, such as improved resolution, sensitivity, etch resistance, and lower line width/edge roughness without pattern collapse because of strong EUV radiation absorption of tin, which have been demonstrated.

### SUMMARY

In a first aspect, the present invention pertains to organotin compounds bearing cyclopentadienyl, sulfur, selenium, or tellurium as photoresists, and/or precursors for photolithography patterning, or thermoelectric materials, particularly extreme ultraviolet radiation (EUV). The present invention is to provide improved resolution sensitivity, etch resistance, and lower line width/edge roughness without pattern collapse for photolithography patterning.

In another aspect, the organotin compounds contain cyclopentadienyl, sulfur, selenium, or tellurium, wherein cyclopentadienyl comprises cyclopentadienyl C₅H₅ group, or substituted cyclopentadienyl C₅HAR, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an amino, cyano, ether, ester, halide, nitro, silyl, thiol, or carbonyl group.

In a further aspect, the invention pertains to radiation sensitive organotin compounds; wherein the organotin compound is one or more selected from below:

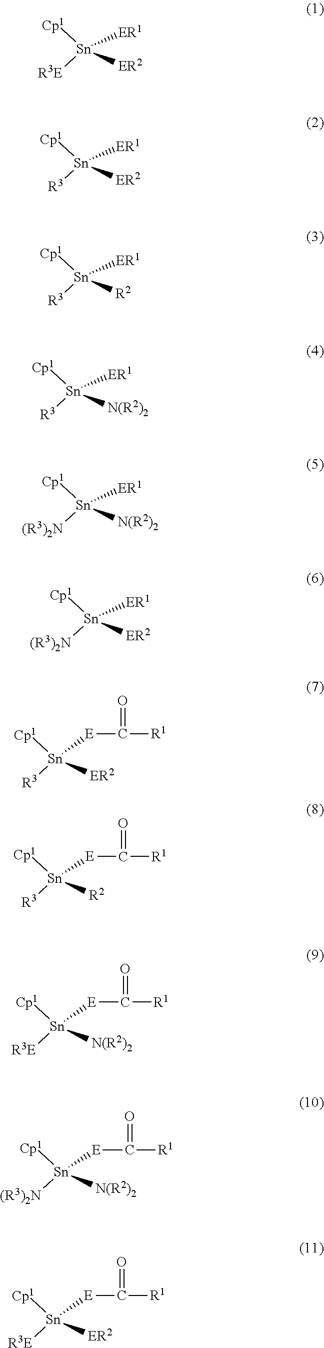

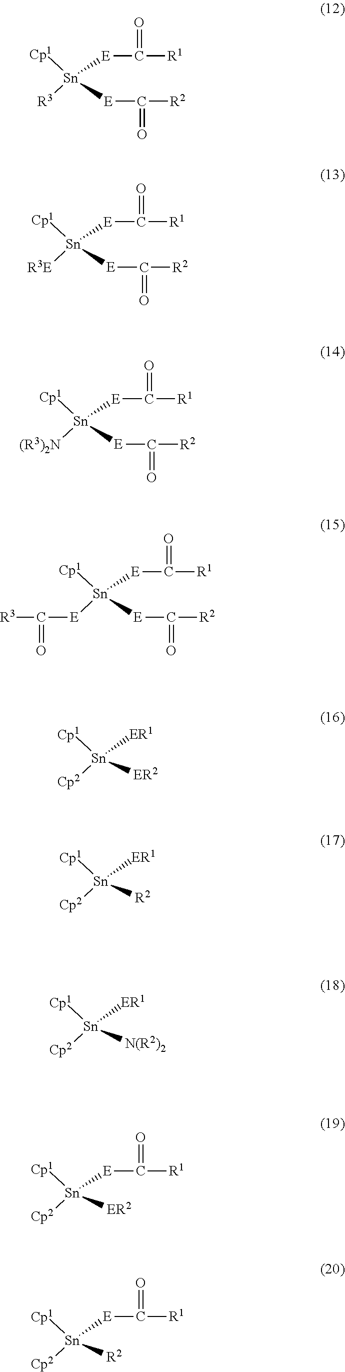

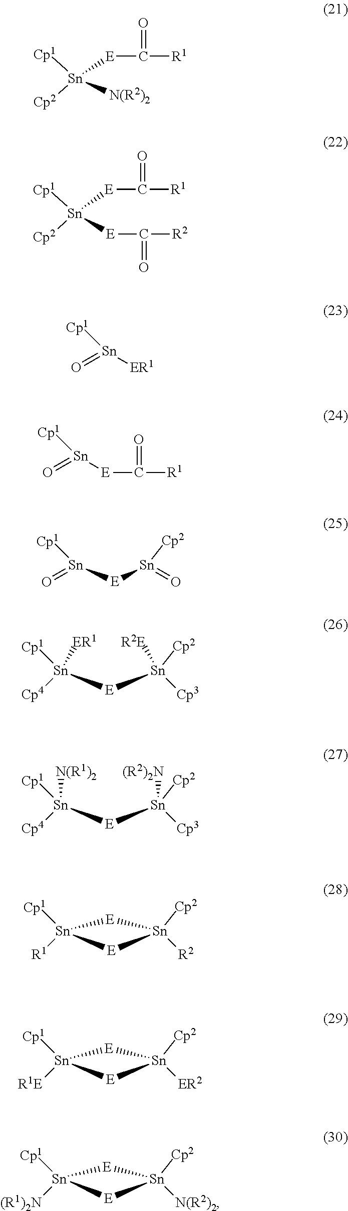

wherein R¹, R², R³ are H, independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; Cp¹, Cp², Cp³, Cp⁴ are independently cyclopentadienyl, wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an amino, cyano, ether, ester, halide, nitro, silyl, thiol, or carbonyl group; E=S, Se, or Te.

The photosensitivity, thermostability and uniformity of organotin photoresist compositions determine high resolution and efficiency of photolithography. The organic molecules stabilized organotin photoresist can dissolve in appropriate organic solvents to form uniformed solution composition for deposition on a surface of substrate for photolithography patterning.

The invention relates to radiation sensitive organotin compound photoresist composition, which can be efficiently patterned after exposure to extreme ultraviolet radiation (EUV), deep ultraviolet radiation (DUV), electron beam radiation, X-ray radiation, or ion-beam radiation, or other likes to form high resolution patterns with low line width roughness, high resolution, low dose and large contrast, such as for <7 nm.

### BRIEF DESCRIPTION OF THE DRAWINGS

FIG. 1 presents chemical formulas (1)-(30) of organotin compounds as photoresists, and/or precursors, which bearing cyclopentadienyl, sulfur, selenium, or tellurium, wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or n′ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an amino, cyano, ether, ester, halide, nitro, silyl, thiol, or carbonyl group.

FIG. 2 illustrates a flowchart of organotin photoresist radiation photolithography patterning processing over a surface of semiconductor substrate.

### DETAILED DESCRIPTION

The present invention pertains to organotin compounds bearing cyclopentadienyl, sulfur (S), selenium (Se), or tellurium (Te) represented by chemical formulas (1)-(30) as photoresists, and/or precursors for photolithography patterning, particularly for extreme ultraviolet radiation (EUV), wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an amino, cyano, ether, ester, halide, nitro, silyl, thiol, or carbonyl group. The present invention is to provide a method of photolithography patterning of organotin compound photoresist composition, particularly, suitable for EUV lithography (e.g. <7 nm). The method of photolithography patterning comprises depositing an organotin compound photoresist composition over a substrate to form a photoresist layer after baking, exposing the photoresist layer to actinic radiation to form a latent pattern; and developing the latent pattern by applying a developer, or sublimation, or vaporization, to remove unexposed or exposed portion of photoresists to form a photolithography pattern. The present invention is further to provide a method of stabilization of organotin photoresist by applying organic molecules as additives to stabilize organotin compounds. Organic molecules stabilized organotin compound photoresists may have higher resolution, sensitivity, solubility, stability, shelf life, and lower line width roughness without pattern collapse during microelectronic patterning. The organotin compounds represented by chemical molecules (1)-(30) also may be used as precursors to prepare other relevant organotin photoresists, such as organotin clusters, organotin polymers, or reaction products from the reactions with second precursor such as water (moisture), oxygen, carbon dioxide, ammonia, borane, or phosphine under ambient conditions. The photosensitivity and thermostability of organotin photoresists determine high resolution and efficiency for photolithography patterning.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched chain hydrocarbon of 1 to 20 carbon atoms. The term “alkenyl” refers to an aliphatic hydrocarbon of 2 to 20 carbon atoms containing at least one carbon-carbon double bond. The term “alkynyl” refers to an aliphatic hydrocarbon of 2 to 20 carbon atoms containing at least one carbon-carbon triple bond. The term “cycloalkyl” refers to cyclic aliphatic hydrocarbon of 3 to 20 carbon atoms. The term “cycloalkenyl” refers to substituted and unsubstituted cyclic aliphatic unsaturated organic groups of 3 to 20 carbon atoms including at least one double carbon-carbon bond hydrocarbon. The term “aryl” refers to unsubstituted or substituted aromatic group with 6 to 20 carbon atoms.

In some embodiments, cycloalkenyl group comprises substituted and unsubstituted C3 to C8 cyclic aliphatic unsaturated organic groups including at least one double bond, for example,

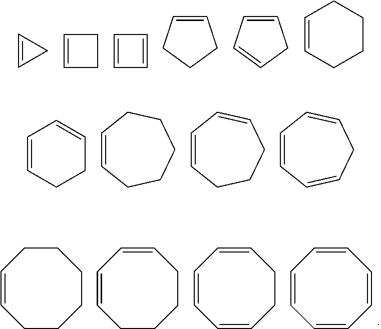

The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like.

The term “amine” refers to primary (—NH₂), secondary (—NHR), or tertiary (—NR₂) amine group. The term “cyclic amine” refers to [R—NH—R′], wherein [R—R′] is cyclic substituted and unsubstituted C₃ to C₈ organic group, including, but not limited to:

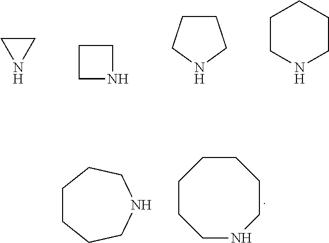

The term “ether” refers to the R—O—R′ group. The term “cyclic ether” refers to the [R—O—R′], wherein [R—R′] is cyclic substituted and unsubstituted C₃ to C₈ organic group, including, but not limited to:

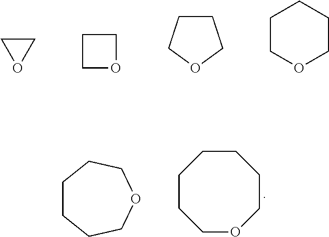

The term “ester” refers to the R—(C═O)—O—R′ group. The term “cyclic ester” refers to the [R—(C═O)—O—R′], wherein [R—R′] is cyclic substituted and unsubstituted C₄ to C₈ organic group, including, but not limited to:

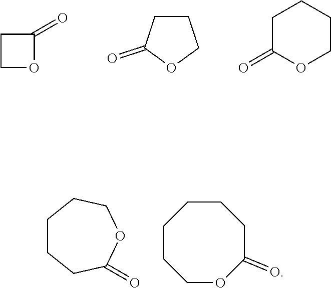

The term “halide” refers to the fluorine (F), chlorine (C₁), bromine (Br), or iodine (I). The term “nitro” refers to the —NO₂. The term “silyl” refers to the —SiR—, —SiR₂—, or —SiR₃ group. The term “thiol” refers to —SH group. The term “thiolate” refers to —SR group. The term “carbonyl” refers to the —C═O group. The term “oxo” refers to —O—, or ═O. In the above described, R, R′ are independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms.

In addition, in the present disclosure, the term “substituted” refers to replacement of a hydrogen atom with a C1 to C20 alkyl group, a C2 to C20 alkene group, a C2 to C20 alkyne group, a C3 to C20 cycloalkyl group, a C6 to C20 aryl group, or other relevant groups including, but not limited to acid, amide, amine, cyano, cyclic amine, ether, cyclic ether, ester, cyclic ester, halide, imine, nitro, silyl, thiol, or carbonyl group, for example, fluoroalkyl, fluorobenzyl, trifluoroacetic acid.

The term “η¹” refers to one carbon atom bonded to one metal atom. The term “η²” refers to two carbon atoms bonded to one metal atom. The term “η³” refers to three carbon atoms bonded to one metal atom. The term “η⁴” refers to four carbon atoms bonded to one metal atom. The term “5” refers to five carbon atoms bonded to one metal atom. In some embodiments, η⁵-compounds comprise sandwich or half-sandwich compounds. For example, η¹, and η⁵ are correspondingly depicted as following (M=metal):

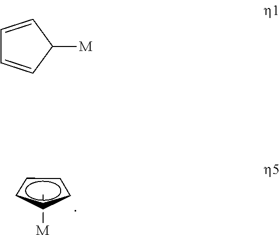

EUV lithography is under the development for the mass production of next generation<7 nm node. EUV photoresists are required to achieve higher performance, higher sensitivity and resolution, and cost reduction.

EUV light has been applied for photolithography at about 13.5 nm. In some embodiments, the EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm, such as 1-3 nm, the conventional chemically amplified (CA) organic polymer photoresists encounter critical issues, such as poor EUV light absorption, low resolution, high line edge roughness (LER) or high line width roughness (LWR), increased pattern collapses and defects. In order to overcome the disadvantages from conventional organic polymer photoresists or inorganic photoresists, novel organometallic photoresists and organometallic photosensitive compositions, particularly for EUV, have been called for.

Organometallic photoresists are used in EUV lithography because metals have high absorption capacity of EUV radiation. Radiation sensitivity and thermal-, oxygen- and moisture-stability are important for organometallic photoresists. In some embodiments, organometallic photoresists may absorb moisture and oxygen, which may result in decreasing stability, as well decreasing solubility in developer solutions. In addition, in some embodiments, photoresist layer may outgas volatile components prior to or during the radiation exposure and/or development operations, which may negatively affect the lithography performance, pattern collapse and increase defects.

In general, metal central plays the key role in determining the absorption of photo radiation.

The physical and chemical properties of organometallic compounds which are suitable for photoresists determine the relevant properties for photolithography, particularly for EUV and DUV, wherein bond dissociated energy (BDE) of M-C (metal-carbon bond) plays a key role. The metal-bonded organic ligands (M-R, M=metal, R=cleavable or hydrolysable organic ligands) may also influence the relevant absorption through M-C bonding. M is metal including but not limited to, tin (Sn), indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), or germanium (Ge). Particularly, organometallic tin photoresists are suitable for EUV or DUV photolithography.

Tin atom provides strong absorption of extreme ultraviolet (EUV) light at 13.5 nm, therein tin cations can be selected based on the desired radiation and absorption cross section. Meanwhile, organic ligand bonded to tin also has absorption of EUV light. Therefore, tuning and modification of organic ligands can change the resolution, sensitivity and radiation absorption, and the desired control of the material properties.

The bond dissociation energy (BDE) of Sn—C bond determines the light absorption wavelength, corresponding smaller features, and patterned structures.

Organotin photoresists have excellent (e.g., suitable) sensitivity to high energy light (e.g., EUV, DUV, X-ray, or laser) due to tin strong absorption of extreme ultraviolet (EUV) at about 13.5 nm. Accordingly, organotin photoresists have improved sensitivity, resolution, stability compared with conventional organic polymer or inorganic photoresists.

Organotin compound photoresists comprise organic ligands, Sn—C bond, or Sn—O bond, or Sn—S bond, or Sn—Se bond, or Sn—Te bond, or Sn—N bond, or Sn—X bond (X=F, Cl, Br, or I), or Sn—O—Sn bond providing desirable radiation sensitive and stabilization for precursor metal cations. The organotin photoresists possess excellent properties for photolithographic patterning.

Organotin compound photoresist composition according to embodiments of the present disclosure may have improved etch resistance, sensitivity and resolution, compared with conventional organic polymer or inorganic resists.

Examples of specific organotin compounds that may be used in implementations of the invention, are represented by chemical formulas (1)-(30) as below:

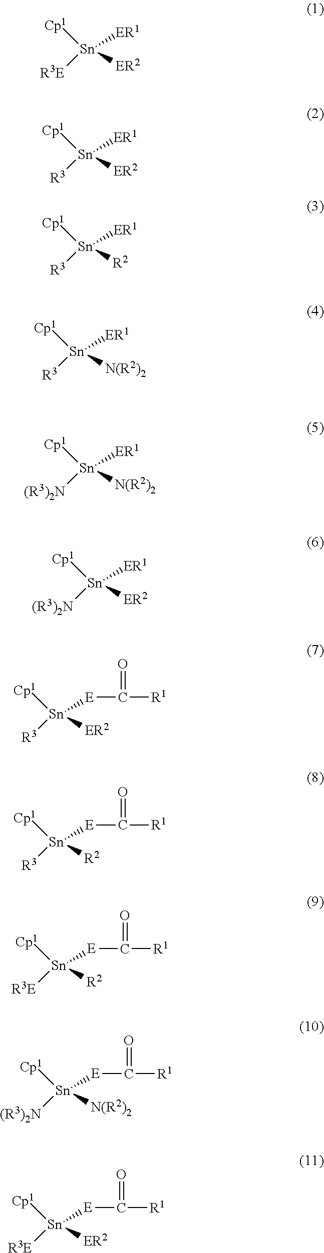

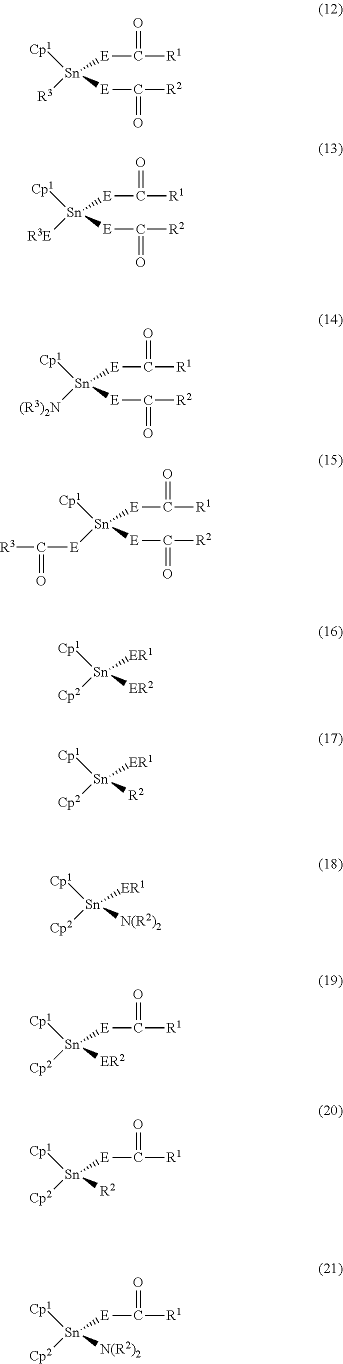

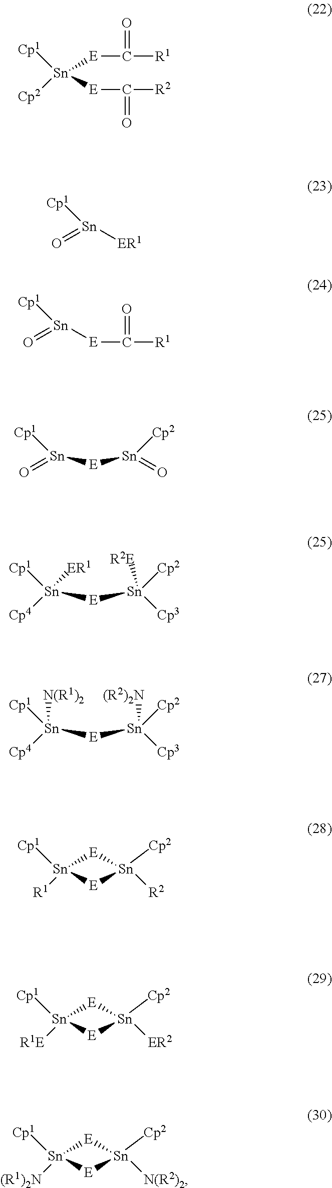

wherein R¹, R², R³ are H, independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an amino, cyano, ether, ester, halide, nitro, silyl, thiol, or carbonyl group; Cp¹, Cp², Cp³, Cp⁴ are independently cyclopentadienyl, wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an amino, cyano, ether, ester, halide, nitro, silyl, thiol, or carbonyl group; E=S, Se, or Te.

For example, in some embodiments, R₁, R₂, R₃ are each independently H, an alkyl, alkenyl, alkynyl, cycloalkyl, cycloalkenyl, or aryl group, for example, methyl (Me), ethyl (Et), isopropyl (i-Pr), n-butyl (n-Bu), t-butyl (t-Bu), t-amyl, s-butyl, pentyl, hexyl, neopentyl (Neo), cyclohexyl, cyclopentyl, cyclobutyl, cyclopropyl, cyclopentadienyl, phenyl (Ph), or benzyl (Ben) group. In some embodiments, R₁, R₂, R₃ comprise fluorine (F), such as fluoride groups.

As one of ordinary skill in the art will recognize, the chemical compounds listed here are merely intended as illustrated examples of organotin compound photoresists, and are not intended to limit the embodiments to only those organotin compound photoresists specifically described. Rather, any suitable organotin compound photoresist may be used, and all such organotin compound photoresists are fully intended to be included within the scope of the present embodiments.

In some embodiments, organotin compounds bearing cyclopentadienyl, sulfur, selenium, or tellurium, represented by chemical formulas (1)-(30), also can be used as precursors for thermoelectric materials, for example, the generation of SnSe, or SnTe thin film.

Organotin compounds represented by chemical formulas (1)-(30) bearing cyclopentadienyl includes hapticity of η¹, η², η³, η⁴, or η⁵ of isomers.

In some embodiments, organotin compounds comprises cyclopentadienyl C₅H₅ group, or substituted C₅HAR, C₅H₃R₂, C₅H₂R₃, C₅HR₄, or C₅R₅ group with hapticity of η¹, η², η³, η⁴, or η⁵ of isomers. A person of ordinary skills in the art will recognize that the structures of cyclopentadienyl or substituted cyclopentadienyl with hapticity of η¹, η², η³, η⁴, or η⁵ of isomers within the explicit ranges of above are contemplated and are within the present disclosure.

For example, in some embodiments, organotin compounds contain cyclopentadienyl C₅H₅, or substituted cyclopentadienyl C₅H₄R, C₅H₃R₂, C₅H₂R₃, C₅HR₄, or C₅R₅ group, wherein R includes, but not limited to, a methyl, ethyl, isopropyl, n-butyl, t-butyl, t-amyl, s-butyl, pentyl, hexyl, neopentyl, cyclohexyl, cyclopentyl, cyclobutyl, cyclopropyl, phenyl, or benzyl group.

Cyclopentadienyl group (C₅R₅, or Cp) may impart photosensitivity to the compounds, and the Cₚ—Sn bond formed may promote suitable solubility in an organic solvent to cyclopentadienyl-containing organotin compound photoresists. Accordingly, these Cₚ—Sn bond containing organotin compounds, according to an embodiment, may have improved sensitivity, resolution and stability, and may suitable for EUV photoresists, and/or the precursors for EUV lithography to form tin-containing film like tin oxide or tin oxide hydroxide film.

The organotin compounds contain cyclopentadienyl-Sn bond (Cₚ—Sn bond). Cₚ—Sn bond is sensitive to UV light and occurs the radiation disruption to generate free radical when exposures to UV light, which has been demonstrated, for example, P. J. Baker, A. G. Davies, M.-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅• radical. This study demonstrated cyclopentadienyl (C₅H₅) group or substituted cyclopentadienyl (C₅R₅) group has higher UV light sensitivity compared with alkyl (e.g., methyl, butyl) groups under identical conditions. This property is beneficial to decrease EUV light dose and increase resolution.

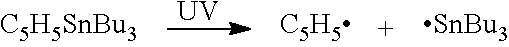

The organotin compounds (1)-(30) contain tin and C—Sn bond, therefore may absorb extreme ultraviolet light at 13.5 nm.

Organotin compound photoresists contain cyclopentadienyl (Cp), or substituted-cyclopentadienyl group, π bond, C—Sn bond and related interaction and may have excellent (e.g., suitable) sensitivity to high energy light (e.g., EUV, or DUV) due to tin absorption high energy EUV ray at 13.5 nm. Accordingly, the related solution compositions may have improved resolution, sensitivity, and stability compared with organic polymer or inorganic photoresists such as metal oxides.

In some embodiments, organotin compound photoresists may have excellent sensitivity to EUV radiation light due to the tin absorption high energy EUV ray at 13.5 nm (low expose dose photoresist, e.g., <20 mJ/cm²), and the disruption of Cₚ—Sn bond to form free radical, tin oxide and relative products, and toughness; low or free pattern defectivity at nanoscale. Accordingly, the solution composition of organotin compound photoresists may have tight pitch (e.g., <10 nm), and may sustain the yield and deliver high resolution.

The organotin compound photoresists bearing unsaturated cycloalkenyl group and C_{cycloalkenyl}—Sn bond, e.g., unsaturated conjugated cyclopentadienyl or substituted-cyclopentadienyl group, according to embodiments of the present disclosure, may have improved etch resistance, sensitivity, and resolution.

The organotin compound (1)-(30) photoresist compositions according to embodiments of the present disclosure may have improved etch resistance, sensitivity and resolution, compared with conventional organic polymer photoresists and inorganic photoresists, wherein oxygen, nitrogen, or various groups are bonded to tin metal as described above.

In some embodiments, organotin compound photoresists may comprise functional groups, including but not limited to, amine, amide, cyano, carbonyl, carboxylic acid, ether, halogen, hydroxy, keto, thiol, silyl, or combinations thereof.

Organotin photoresist composition may include 0.1 wt % to 60 wt % of the organotin compounds represented by chemical formulas (1)-(30), based on the total weight of the organotin photoresist composition. A person of ordinary skills in the art will recognize that the samples, concentrations, and amounts of organotin compounds within the explicit ranges of above are contemplated and are within the present disclosure.

Organotin compounds as photoresists are soluble in appropriate organic solvents for further photolithography pattern processing. The solution composition of organotin compounds can be utilized as EUV photoresists for further processing and patterning.

In some embodiments, organotin compound photoresists are soluble in appropriate organic solvents with improved uniformity for photolithography pattern processing. The solution compositions can be formed by dissolving organotin compound photoresists in organic solvents, including but not limit to, pentane, hexane, cyclohexane, dichlomethane, chloroform, tetrahydrofuran, dimethoxyethane, dimethylformamide, dimethyl sulfoxide, alcohols (e.g., 4-methyl-2-pentenol, methanol, ethanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. A person of ordinary skills in the art will recognize that the choice of solvents and solution composition components within the explicit ranges of above are contemplated and are within the present disclosure.

In some embodiments, the solution composition of organotin compound photoresists containing cyclopentadienyl or substituted-cyclopentadienyl group, according to embodiments of the present disclosure, may have relatively improved etch resistance, sensitivity and resolution, compared with related conventional organic polymer or inorganic photoresists, wherein oxygen, nitrogen, or various groups are bonded to tin metal as described above.

In some embodiments, the organotin compounds represented by chemical formulas (1)-(30) may be used as precursors to prepare other organotin compounds as photoresists, or organotin photoresist compositions, for example, hydrolysis with water or moisture to form organotin cluster photoresist, or reaction with oxygen sources such as oxygen, air, ozone, or hydroperoxide.

In some embodiments, organotin compounds as precursors for preparation of organotin photoresists, according to embodiments of the present disclosure, may be represented by at least one of examples. Examples of specific organotin photoresist materials that may be used in implementations of the invention are presented by chemical formulas (1)-(30), which contain hydrolysable functional groups, such as —SR, —SeR, —TeR, —N(R)₂, or -E-(C═O)—R.

In some embodiments, an organotin photoresist precursor solution deposits over the surface of substrate or layer to form photoresist layer through in situ hydrolysis with water, or alternative bases like tetramethyl ammonium hydroxide. The baking of the formed photoresist layer at an elevated temperature result in hydrolysis of organometallic compound and subsequent condensation to form organometallic tin oxide hydroxide clusters. After exposure to EUV lithography or e-beam lithography, pattering radiation causes Sn—C bond cleavage and crosslinking of the organotin compounds in the exposed portions of photoresists, and then resulted in a stable metal oxide (MOₓ).

The radiation sensitive organotin photoresists comprise polynuclear oxo or oxo-hydroxide networks, and/or alkyl ligands. However, the poor stability of conventional organotin or organotin cluster photoresists in solution after aged would lead to aggregation or precipitation with short shelf life for photolithography, which then would result in scums or defects in photolithography patterning.

In some embodiments, the addition of additives may increase the stability of the radiation sensitive organotin compound photoresist composition.

In some embodiments, the stability of organotin photoresists in solution can be improved by organic molecules as stabilizers. The organic molecules-stabilized organotin photoresists possess improved stability, solubility, uniformity, or shelf life for photolithography patterning.

In some embodiments, organic molecule as stabilizing additive includes, but not limited to, organic thiol, organic alcohol, organic amine, organic amide, organic carboxylic acid, organic phosphine, phosphine oxide, or organic phosphonic acid. A person of ordinary skills in the art will recognize that organic molecules, concentrations, and solution composition components within the explicit ranges of above are contemplated and are within the present disclosure.

In some embodiments, organic thiol includes, but not limited to, 1-dodecanethiol, 2-dodecanethiol, 1,12-dodecanedithiol, 1-docosanethiol, 1-decanethiol, 1-heptanethiol, 2-heptanethiol, 1-heptadecanethiol, 1-hexanethiol, 1-hexadecanethiol, 1-nonanethiol, 1-octadecanethiol, 1-octanethiol, 1-pentadecanethiol, 1-tetradecaenthiol, 1-tridecanethiol, 1-undecanethiol, 1,8-octanedithiol, 1,2-ethanedithiol, or a combination thereof.

In some embodiments, organic alcohol includes, but not limited to, 1-dodecanol, 1-octanol, 1-hexadecanol, 1-heptanol, 1-heptadecanol, 1-decanol, 1-undecanol, 1-dodecanol, 1-tridecanol, 1-tetradecaonl, 1-nonaol, 1,10-decanediol, 1,2-hexadecanediol, 1,12-dodecanediol, 1,8-octanediol, 1,11-undecanediol, 2-mercaptoethanol, or a combination thereof.

In some embodiments, organic amine includes, but not limited to, 1-heptadecyloctadecylamine, decylamine, dodecylamine, heptylamine, heptadecylamine, hexadecylamine, isotridecanamine, nonylamine, octadecylamine, octanamine, octylamine, pentadecylamine, tetradecylamine, tridecylamine, triethylamine, undecylamine, undecanamine, 1,8-diaminooctane, 1,9-diaminononane, 1,12-dodecanediamine, 1,11-undecanediamine, or a combination thereof.

In some embodiments, organic amide includes, but not limited to, decanamide, docosanamide, dodecanamide, heanoamide, heptanamide, heptadecanamide, hexadecanamide, icosanamide, nonanamide, nonadecanamide, nonaediamide, octanamide, oleamide, octadecanamide, octanediamide, pentadecanamide, tetradecanamide, tridecanamide, undecanamide, or a combination thereof.

In some embodiments, organic carboxylic acid includes, but not limited to, oleic acid, citric acid, decanoic acid, hexadecanedioic acid, lauric acid, nonanoic acid, octanoic acid, palmitic acid, suberic acid, undecanoic acid, 1,11-undecanedicarboxylic acid, thiolglycolic acid, mercaptoacetic acid, mercaptopropionic acid, or a combination thereof.

In some embodiments, organic phosphine, phosphine oxide, or phosphonic acid, include, but not limited to, trioctylphosphine, tributylphosphine, tris(dimethylamino)phosphine, tris(diethylamino)phosphine, trioctylphospine oxide, hexylphosphonic acid, octadecylphosphonic acid, 11-undecenyl phosphonic acid, or a combination thereof.

In some embodiments, organic molecules stabilizers may be adsorbed, grafted, immobilized, anchored, or coordinated on organotin compound photoresists as supports.

In some embodiments, organic molecules stabilized organotin compound photoresist composition according to an embodiment can be prepared by the addition of organic molecular stabilizer to the solution of organotin compound under ambient condition. A person of ordinary skills in the art will recognize that the temperatures and addition rates within the explicit ranges of above are contemplated and are within the present disclosure.

The solution composition of organotin compound photoresists can be utilized for photolithography patterning including extreme ultraviolet radiation (EUV) (13.5 nm), deep ultraviolet radiation (DUV) such as KrF excimer laser (248 nm) or ArF excimer laser (193 nm), e-beam radiation, X-ray radiation, or ion-beam radiation for further processing and patterning.

The general photolithography process comprises (1) forming an organotin compound photoresist composition; (2) depositing photoresist composition over a substrate (e.g., silicon, silicon oxide) to form a thin film; (3) then pre-exposure baking at appropriate temperature; (4) exposing to actinic radiation (e.g., EUV) to form a latent image, followed by after post-exposure baking; (5) then developing with a developer (e.g., aqueous basic/acid solutions or organic solvents); or sublimation, or evaporation to remove the selected portion of photoresists; (6) and then rinsing with solvent to produce to form a photolithography pattern.

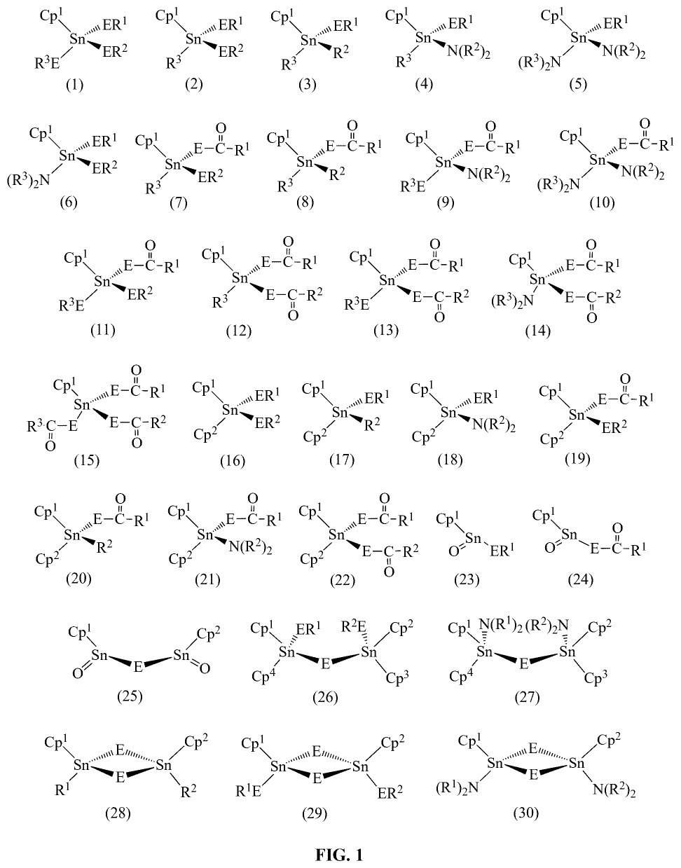

The present invention encompasses organotin compound photoresist compositions for photolithography patterning. Herein organotin compounds are represented by chemical formulas (1)-(30) of FIG. 1. The photolithography patterning comprises forming an organotin photoresist composition; wherein the forming the organotin photoresist composition comprises an organotin compound, a solvent, and/or an additive; organotin compound photoresist may be stabilized by organic molecules as additives. The formed organotin photoresist composition is then deposited over a substrate such as silicon, silicon oxide to form photoresist layer. After baking at appropriate temperature, the organotin photoresist layer is exposed to actinic radiation to form a latent pattern. The formed latent pattern is developed by applying a developer to remove the unexposed, or exposed portion of photoresists to form a photolithography pattern.

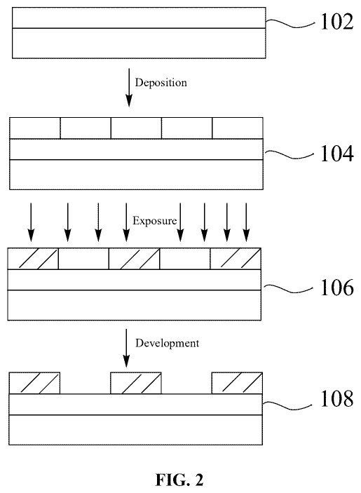

In the present disclosure, a method of forming photolithography pattern using the organotin photoresist composition is illustrated by FIG. 2.

The general photolithography process described by FIG. 2, is to deposit photoresist over a substrate 102 to form a thin photoresist layer 104; after pre-exposure baking, the formed layer is exposed to actinic radiation to form a latent image 106; after post-exposure baking, the latent is developed by the appropriate developer, such as aqueous basic/acid solutions or organic solvents, to produce the developed resist photolithography pattern 108.

In an embodiment, organotin photoresists is deposited on a surface of semiconductor substrate by wet deposition like spin-on coating, spray coating, dip coating, or knife edge coating. In another embodiment, organotin photoresist is deposited by dry deposition like chemical vapor deposition (CVD), atomic layer deposition (ALD), physical vapor deposition (PVD), or the like over the surface of substrate.

In some embodiments, after exposure, the exposed and unexposed portion of organotin photoresists possess different chemical and physical properties. Organic ligands of organotin photoresists can be cleaved to form metal oxide or polynuclear oxo/hydroxo network patterns. The exposed or unexposed portion of photoresists may be removed by appropriate wet or dry developer, such as organic solvent or aqueous solution, according to different features, solubility and properties.

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), aromatic solvents (e.g., benzene, toluene, xylene), acid (e.g., formic acid, acetic acid, oxalic acid, 2-ethylhexanonic acid), and combinations thereof.

In some embodiments, the wet liquid solvent developing process is applied by dipping the exposed/unexposed substrates into a developer bath. In some embodiments, the wet solvent developing solution can be sprayed into the exposed/unexposed photoresists layer.

In some embodiments, the developer is a dry developer including, but not limited to, Cl₂, CH₂Cl₂, BF₃, BCl₃, CF₄, CCl₄, HBr, or a combination thereof.

In some embodiments, the developing method includes sublimation or vaporization under reduced pressure (e.g. in the range of 0.0001 torr to 100 torr) at ambient temperature (e.g. in the range of 20 to 300° C.). A person of ordinary skills in the art will recognize that the reduced pressures and temperatures within the explicit ranges of above are contemplated and are within the present disclosure.

In an embodiment, the actinic radiation is extreme ultraviolet radiation (EUV), or deep ultraviolet radiation (DUV). In another embodiment, the actinic radiation is e-beam radiation, X-ray radiation, or ion-beam radiation.

The invention pertains to the methods for preparation and purification of organotin compounds represented by chemical formulas (1)-(30) of FIG. 1. In some embodiments, all chemical manipulations, including preparation and purification, are performed under an inert atmosphere of purified nitrogen or argon in dry and degassed solvents by employing standard Schlenk techniques. The methods for purification include, but not limited to, distillation, extraction, filtration, recrystallization, column chromatography, coordination, sublimation, vaporization, or combinations thereof.

In some embodiments, the stability, solubility, and uniformity of organotin compound photoresist composition may be improved, and dissolution during a photolithography such as EUV or DUV. Accordingly, a photolithography pattern having improved stability, solubility, sensitivity and resolution may be afforded by using of organotin compound photoresist. The as-formed pattern by using of organotin compound photoresist composition may not form scums and defects.

In addition, organotin compound photoresist compositions for photolithography patterning according to an embodiment is not necessarily limited to negative tone image but may be formed to have a positive tone image.

Organotin compound photoresists have advantages compared with conventional organic polymer photoresists or inorganic photoresists. However, it will be understood that not all the advantages have been necessarily discussed herein to include all embodiments or examples, other embodiments or examples may offer different advantages.

Hereinafter, the present invention is described in more details through Examples regarding the preparation of organotin compounds as photoresists, and/or as precursors for photolithography patterning, or thermoelectric materials. However, the present invention is not limited by the Examples. The following examples are provided for further illustration of certain embodiments of the disclosure, which is not necessarily limited to these embodiments.

### EXAMPLES

### Example 1

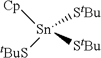

Synthesis of CpSn(S′Bu)₃. To a solution of CpSnCl₃ (206 mg, 1.2 mmol) in toluene (50 mL), NaS^{t}Bu (403 mg, 3.6 mmol) was added with vigorously stirring. After stirred at room temperature overnight, the reaction mixture was filtered through Celite. Then the filtrate was evaporated in vacuo to give the product. Yield: 376 mg, 70%. MS (EI): m/z 451 (M⁺).

### Example 2

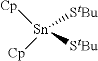

Synthesis of Cp²Sn(S^{t}Bu)₂. At 0° C., to a solution of Cp²SnCl₂ (351 mg, 1.1 mmol) in toluene (50 mL), NaS^{t}Bu (260 mg, 2.32 mmol) was added with vigorously stirring. Then the mixture was stirred at room temperature overnight. After filtered through short pad of silicon, the filtrate was evaporated in vacuo to give the product. Yield: 290 mg, 62%. MS (EI): m/z 427 (M⁺).

It is understood that the above-described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the spirit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin photoresist composition for photolithography patterning, comprising:
an organotin compound, a solvent, and/or an additive;
wherein the organotin compound is one or more selected from below: 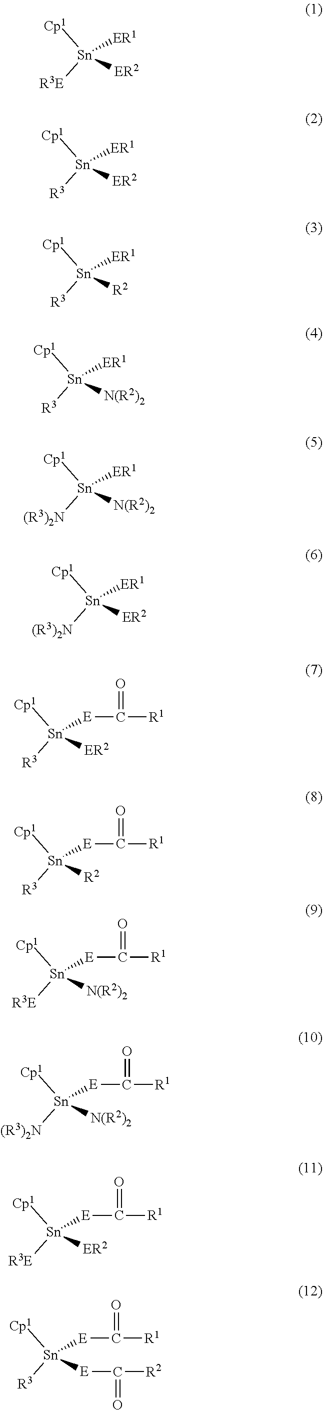 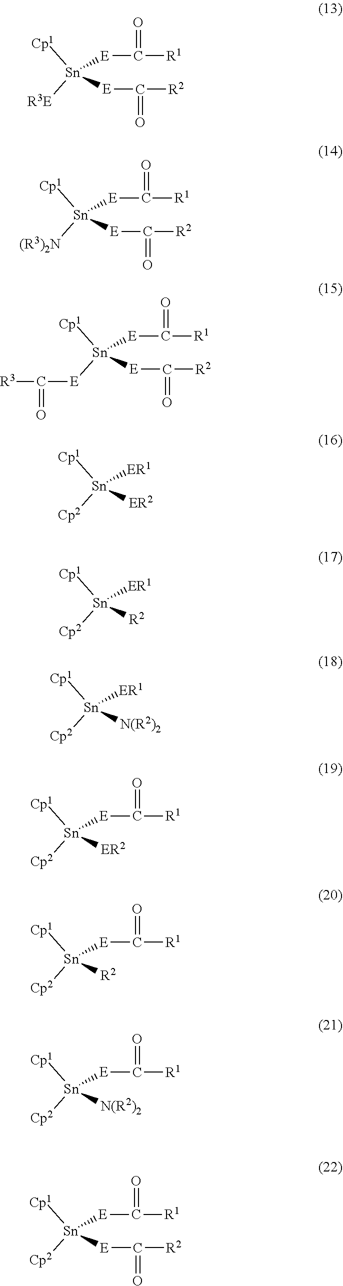 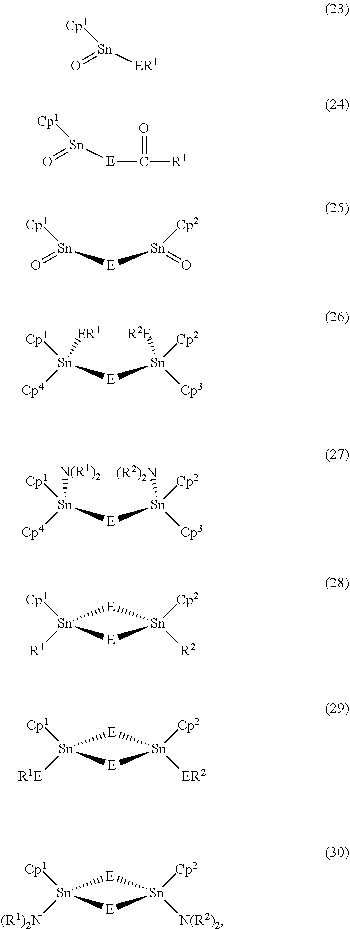
wherein R¹, R², R³ are H, each independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; Cp¹, Cp², Cp³, Cp⁴ are each independently cyclopentadienyl, wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; E=S, Se, or Te.

2. The organotin photoresist composition of claim 1, wherein R is a methyl, ethyl, propyl, n-butyl, t-butyl, phenyl, benzyl, or cyclohexyl group.

3. The organotin photoresist composition of claim 1, wherein Cp¹, Cp², Cp³, Cp⁴ are cyclopentadienyl C₅H₅.

4. The organotin photoresist composition of claim 1, wherein R¹, R², R³ are each independently a substituted or unsubstituted alkyl.

5. The organotin photoresist composition of claim 1, wherein substituted comprises fluorine.

6. The organotin photoresist composition of claim 1, wherein the additive comprises organic thiol, organic alcohol, organic amine, organic amide, organic carboxylic acid, organic phosphine, organic phosphine oxide, organic phosphonic acid, or a combination thereof.

7. The organotin photoresist composition of claim 1, wherein photolithography patterning includes extreme ultraviolet radiation, deep ultraviolet radiation, e-beam radiation, X-ray radiation, or ion-beam radiation.

8. A method for photolithography patterning, comprising:
depositing an organotin compound photoresist composition over a substrate;
exposing the organotin photoresist layer to actinic radiation to form a latent pattern; and
developing the latent pattern by applying a developer, or sublimation to remove unexposed or exposed portion of photoresists to form a photolithography pattern.

9. The method of claim 8, wherein the organotin compound is one or more selected from below: 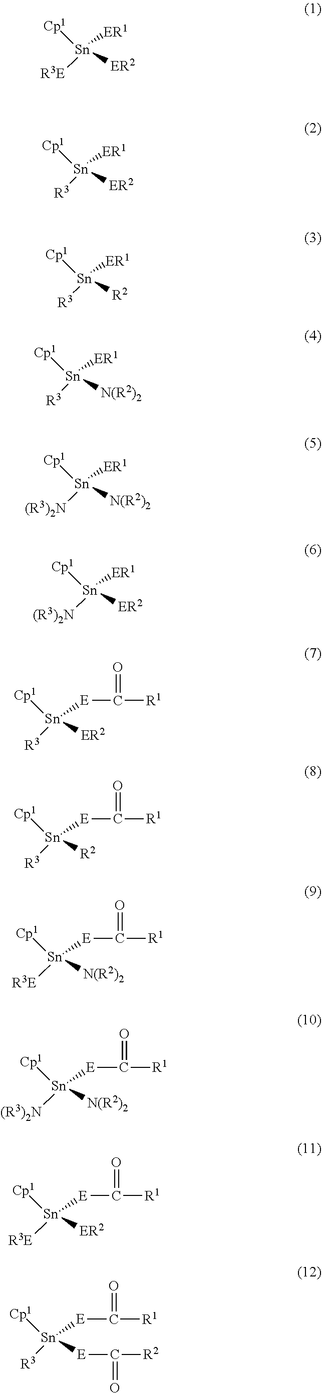 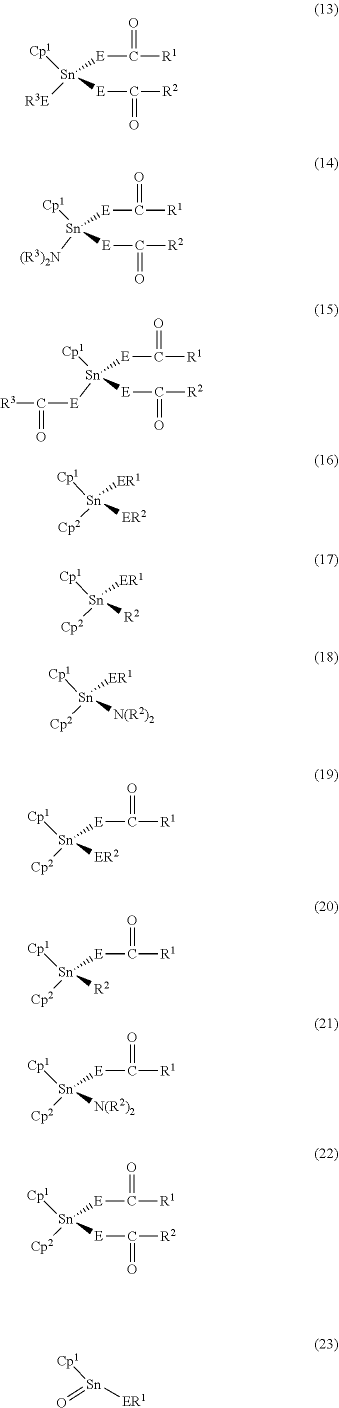 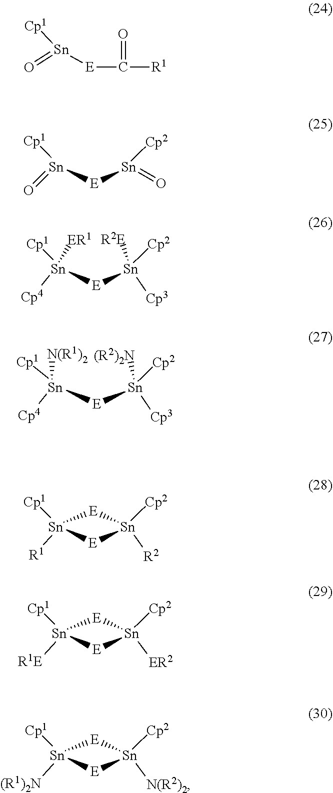
wherein R¹, R², R³ are H, independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; Cp¹, Cp², Cp³, Cp⁴ are independently cyclopentadienyl, wherein cyclopentadienyl comprises cyclopentadienyl C₅H₅ group, or substituted cyclopentadienyl C₅HAR, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms;
E=S, Se, or Te.

10. The method of claim 9, wherein substituted comprises fluorine.

11. The method of claim 9, wherein R is a methyl, ethyl, propyl, n-butyl, t-butyl, phenyl, benzyl, or cyclohexyl group.

12. The method of claim 9, wherein Cp¹, Cp², Cp³, Cp⁴ are cyclopentadienyl CHs.

13. The method of claim 8, wherein actinic radiation is extreme ultraviolet radiation, or deep ultraviolet radiation.

14. An organotin photoresist, having a chemical formula selected from the following: 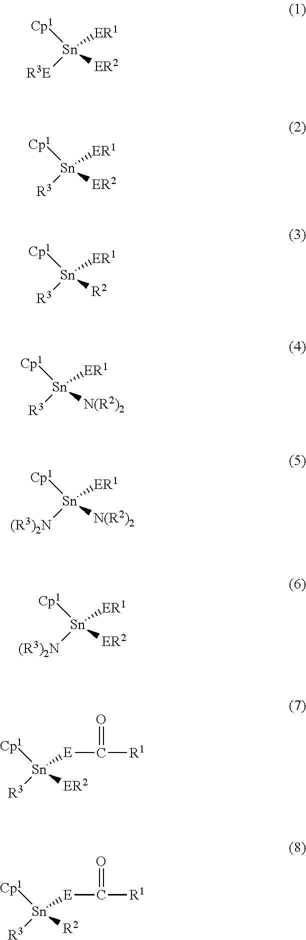 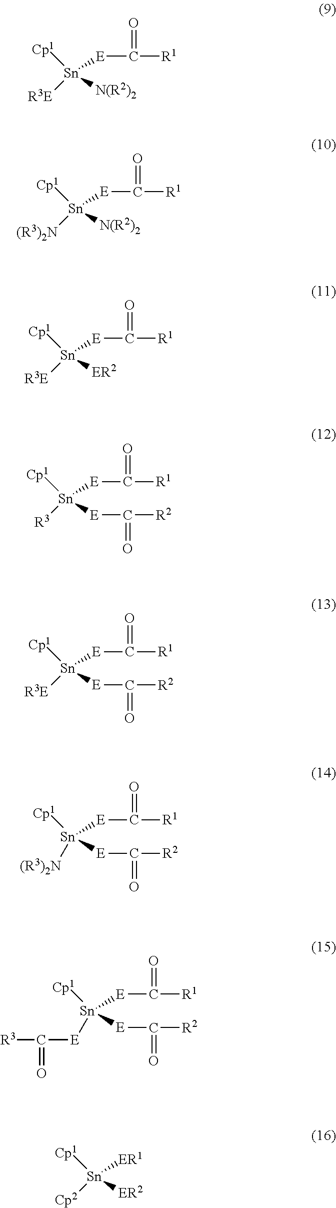 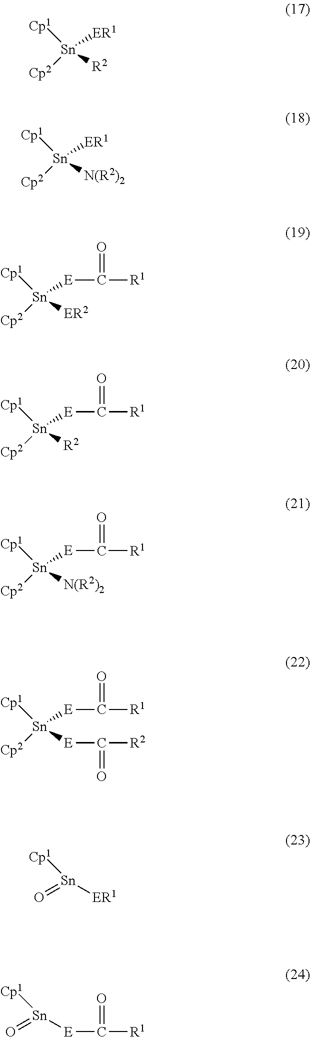 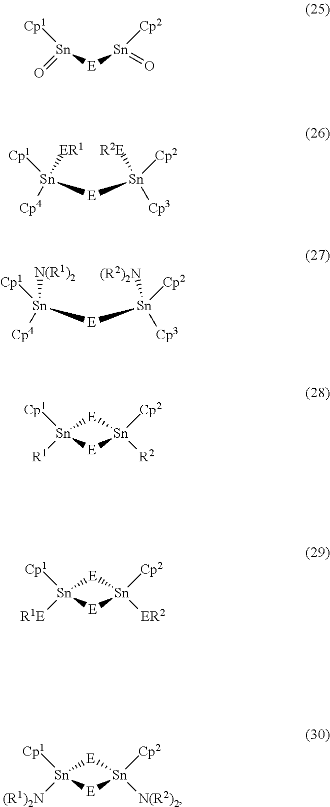
wherein R¹, R², R³ are H, each independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; Cp¹, Cp², Cp³, Cp⁴ are independently cyclopentadienyl, wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms;
E=S, Se, or Te.

15. The organotin photoresist of claim 14, wherein cycloalkenyl group comprises substituted or unsubstituted C₄ to C₈ cyclic aliphatic unsaturated organic groups including at least one double bond.

16. The organotin photoresist of claim 14, wherein substituted comprises fluorine.

17. The organotin photoresist of claim 14, wherein R is a methyl, ethyl, propyl, n-butyl, t-butyl, phenyl, benzyl, or cyclohexyl group.

18. The organotin photoresist of claim 14, wherein Cp¹, Cp², Cp³, Cp⁴ are cyclopentadienyl C₅H₅.

19. The organotin photoresist of claim 14, wherein R¹, R², R³ are each independently an alkyl, or a cycloalkenyl group.

20. The organotin photoresist of claim 14, wherein the organotin represented by chemical formulas (1)-(30) may also be used as precursors for photoresists, or thermoelectric materials.
